(19) United States
(12) Patent Application Publication
(10) Pub. No.: US 2025/0366007 A1
(43) Pub. Date: Nov. 27, 2025

(54) ISOLATION STRUCTURES IN SEMICONDUCTOR DEVICES

(71) Applicant: Taiwan Semiconductor Manufacturing Company, Ltd., Hsinchu (TW)

(72) Inventors: Yi-Hong LIN, Hsinchu (TW); I-Hsieh WONG, Hsinchu (TW); Tzu-Hua CHIU, Hsinchu (TW); Cheng-Yi PENG, Taipei City (TW); Chia-Pin LIN, Xinpu Township (TW)

(73) Assignee: Taiwan Semiconductor Manufacturing Company, Ltd., Hsinchu (TW)

(21) Appl. No.: 19/291,189

(22) Filed: Aug. 5, 2025

Related U.S. Application Data
(63) Continuation of application No. 18/124,980, filed on Mar. 22, 2023.
(60) Provisional application No. 63/374,270, filed on Sep. 1, 2022.

(51) Int. Cl. H10D 30/43; H10D 30/01; H10D 30/67; H10D 62/10; H10D 64/23

(52) U.S. Cl. CPC H10D 30/43; H10D 30/014; H10D 30/6735; H10D 62/116; H10D 62/121; H10D 64/258

(57) ABSTRACT

A semiconductor device and a method of fabricating the semiconductor device are disclosed. The semiconductor device includes a substrate, a fin base disposed on the substrate, nanostructured channel regions disposed on a first portion of the fin base, a gate structure surrounding the nanostructured channel regions, a source/drain (S/D) region disposed on a second portion of the fin base, and an isolation structure disposed between the S/D region and the second portion of the fin base. The isolation structure includes an undoped semiconductor layer disposed on the second portion of the fin base, a silicon-rich dielectric layer disposed on the undoped semiconductor layer, and an air spacer disposed on the silicon-rich dielectric layer.

### CROSS-REFERENCE TO RELATED APPLICATION

This application is a continuation of U.S. patent application Ser. No. 18/124,980, titled “Isolation Structures in Semiconductor Devices,” filed Mar. 22, 2023, which claims the benefit of U.S. Provisional Patent Application No. 63/374,270, titled “3D FET Device and Method for Forming the Same,” filed on Sep. 1, 2022, each of which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), fin field effect transistors (finFETs), and gate-all-around (GAA) FETs. Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device with an isolation structure, in accordance with some embodiments.

FIGS. 1B and 1C illustrate cross-sectional views of a semiconductor device with an isolation structure, in accordance with some embodiments.

FIG. 2 is a flow diagram of a method for fabricating a semiconductor device with an isolation structure, in accordance with some embodiments.

FIGS. 3-16 illustrate cross-sectional views of a semiconductor device with an isolation structure at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

GAA FETs can include fin bases disposed on a substrate, stacks of nanostructured channel regions disposed on the fin bases, gate structures surrounding each of the nanostructured channel regions, and inner spacers on sidewalls of the gate structures. The GAA FETs can further include S/D regions, each of which can be disposed between a pair of nanostructured channel regions and on a fin portion of the fin base between the pair of nanostructured channel regions. Each of the S/D regions can be formed by the merging of an epitaxial portion grown on the fin portion with epitaxial portions grown on sidewalls of the pair of nanostructured channel regions. Due to the growth of the S/D regions on the fin portions, there may be current leakage between adjacent S/D regions on the same fin base.

To address the abovementioned challenges, the present disclosure provides examples methods of forming isolation structures between the epitaxial S/D regions and fin bases. These isolation structures can electrically isolate the epitaxial S/D regions from the underlying fin bases, and as a result prevent or minimize current leakage between adjacent S/D regions on the same fin base. In some embodiments, each of the isolation structures can include an undoped semiconductor layer, a dielectric layer disposed on the semiconductor layer, and an air spacer disposed on the dielectric layer. In some embodiments, the undoped semiconductor layer can include an undoped silicon layer epitaxially grown in a portion of the fin base under the epitaxial S/D region. In some embodiments, the dielectric layer can include a silicon-rich dielectric material. As used herein, the term “silicon-rich dielectric material” refers to a dielectric material with a non-stoichiometric composition, which has a concentration ratio of silicon to any other chemical element of the dielectric material higher than that of the dielectric material with a stoichiometric composition. In some embodiments, the silicon-rich dielectric material can include (i) silicon-rich nitride (SiₓN_{y}) with a concentration of silicon atoms higher than the concentrations of nitrogen atoms, (ii) silicon-rich oxynitride (SiₓO_{y}N_{z}) with a concentration of silicon atoms higher than the concentrations of oxygen atoms and nitrogen atoms, (iii) silicon-rich oxycarbide (SiₓO_{y}C_{z}) with a concentration of silicon atoms higher than the concentrations of oxygen atoms and carbon atoms, or (iv) other suitable silicon-rich nitride- or carbide-based dielectric materials.

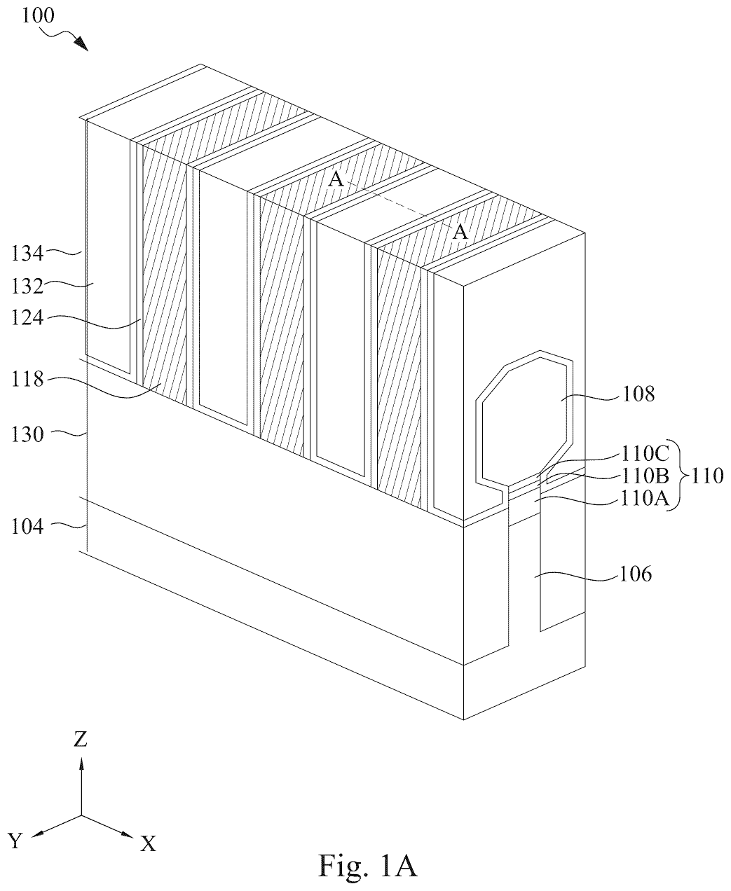

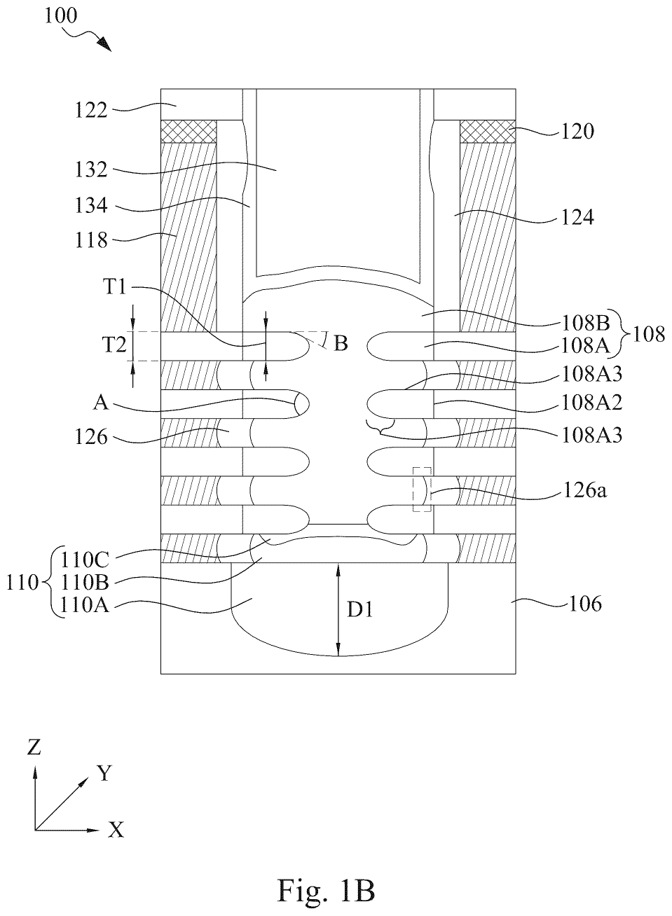

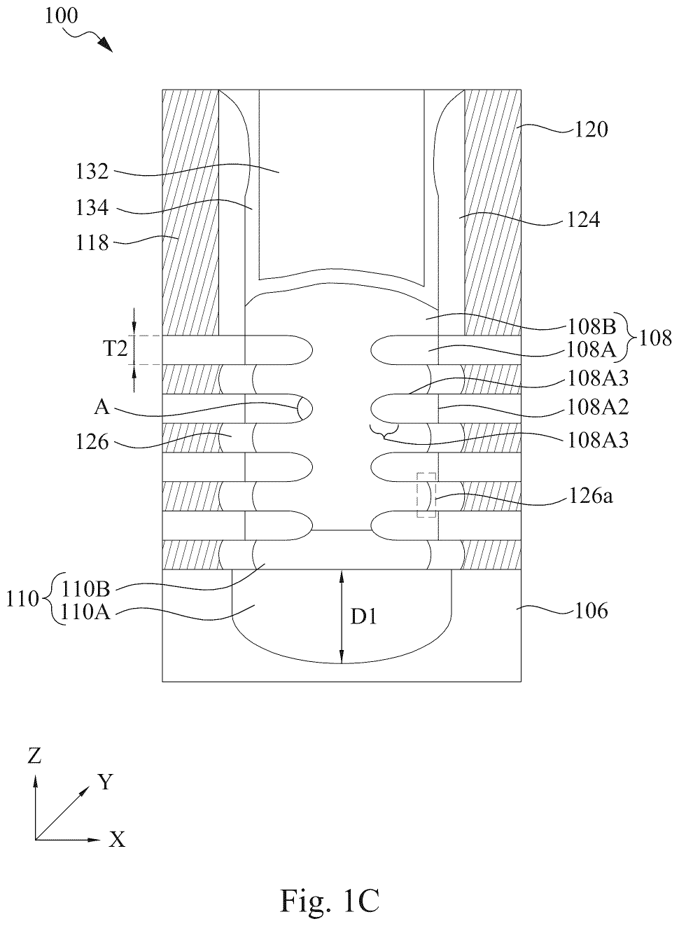

FIG. 1A illustrates an isometric view of a FET 100 (also referred to as a “GAA FET 100”), according to some embodiments. FIGS. 1B and 1C illustrate different cross-sectional views of FET 100, along line A-A of FIG. 1A, according to some embodiments. FIGS. 1B and 1C illustrate the cross-sectional views of FET 100 with additional structures that are not shown in FIG. 1A for simplicity. The discussion of elements with the same annotations applies to each other, unless mentioned otherwise. In some embodiments, FET 100 can represent n-type FET 100 (NFET 100) or p-type FET 100 (PFET 100) and the discussion of FET 100 applies to both NFET 100 and PFET 100, unless mentioned otherwise. In some embodiments, NFET 100 and PFET 100 can be formed on the same substrate.

Referring to FIGS. 1A and 1B, in some embodiments, FET 100 can include (i) a substrate 104, (ii) a fin base 106, (iii) S/D regions 108, (iv) isolation structures 110, (v) nanostructured channel regions 116, (vi) gate structures 118, (vii) conductive capping layers 120, (viii) insulating capping layers 122, (ix) outer gate spacers 124, (x) inner gate spacers 126, (xi) shallow trench isolation (STI) regions 130, (xii) interlayer dielectric (ILD) layers 132, and (xiii) etch stop layers (ESLs) 134.

In some embodiments, substrate 104 can be a semiconductor material, such as silicon, germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). In some embodiments, other FETs similar to FET 100 can be formed on substrate 104. In some embodiments, PFET 100 and NFET 100 can be formed on different regions of substrate 104. In some embodiments, PFET 100 and NFET 100 can be formed adjacent to each other and can have common elements, such as gate structures, gate spacers, ILD layers, ESLs, and STI regions.

In some embodiments, fin base 106 can be formed by patterning and etching substrate 104. Thus, fin base 106 can include materials similar to that of substrate 104. In some embodiments, fin base 106 of PFET 100 can include n-type dopants (e.g., phosphorus or arsenic) and fin base 106 of NFET 100 can include p-type dopants (e.g., boron, indium, aluminum, or gallium).

In some embodiments, each S/D region 108 can be disposed above fin base 106 and can be electrically isolated from fin base 106 by isolation structure 110. In some embodiments, each S/D region 108 can include S/D sub-regions 108A and 108B. S/D sub-regions 108A can be disposed directly on and can be epitaxially grown on sidewalls of nanostructured channel regions 116. In some embodiments, each S/D sub-region 108A can have (i) elongated sides 108A1 extending along an X-axis, (ii) a sidewall 108A2 with a substantially linear (shown in FIGS. 1B and 1C) or curved (not shown) cross-sectional profile in contact with respective nanostructure channel region 116, and (iii) a tip region 108A3 with a tapered cross-sectional profile in contact with S/D sub-region 108B.

In some embodiments, tip regions 108A3 can have vertex angles A of about 70 degrees to about 90 degrees. In some embodiments, elongated sides 108A1 can form angles B of about 35 degrees to about 45 degrees with sidewalls of tip regions 108A3. In some embodiments, each S/D sub-regions 108A can have a thickness T1 substantially equal to a thickness T2 of nanostructured channel regions 116. In some embodiments, thicknesses T1 and T2 can have a ratio (T1:T2) of about 1:1 to about 1:4. Within these ranges of angles A and B and thickness T1, adjacent S/D sub-regions 108A can be prevented from merging with each other. Furthermore, forming the bottommost S/D sub-regions 108A with these ranges of angles A and B and thickness T1 can facilitate the formation of isolation structures 110, as described in detail below. The number of S/D sub-regions 108A in each S/D region 108 can be equal to the number of nanostructured channel regions 116 facing each S/D region 108. For example, as shown in FIG. 1B, each S/D region 108 includes eight S/D sub-regions 108A, which is equal to the eight nanostructured channel regions 116 facing each S/D region 108.

In some embodiments, each S/D region 108B can include (i) first portions disposed directly on and can be epitaxially grown on S/D sub-regions 108A, and (ii) second portions disposed directly on sidewalls of inner gate spacers 126 and between adjacent S/D sub-regions 108A. The second portions of S/D sub-regions 108B can be formed by the merging of adjacent first portions of S/D sub-regions 108B. In some embodiments, an air gap (not shown) can be present between the sidewalls of inner gate spacers 126 and the second portion of S/D sub-regions 108B. The epitaxial growth of S/D sub-regions 108B can be controlled to prevent them from extending to inner gate spacers 126 that are disposed directly on fin base 106. That is, S/D sub-regions 108B are not in contact with inner gate spacers 126 that are disposed directly on fin base 106.

In some embodiments, for NFET 100, S/D sub-regions 108A and 108B can include epitaxially-grown Si without any Ge atoms and can differ from each other based on n-type dopant (e.g., phosphorus atoms) concentrations. For example, S/D sub-regions 108B can have an n-type dopant concentration higher than that in S/D sub-regions 108A. A higher dopant concentration in S/D sub-regions 108B can reduce contact resistance between S/D regions 108 and S/D contact structures (not shown). In some embodiments, S/D sub-regions 108A can be undoped. In some embodiments, S/D sub-regions 108B can include a phosphorus dopant concentration of about 1×10²¹ atoms/cm³ to about 4×10²¹ atoms/cm³.

In some embodiments, for PFET 100, S/D sub-regions 108A can include epitaxially-grown Si without any Ge atoms and S/D sub-regions 108B can include epitaxially-grown SiGe. In some embodiments, S/D sub-regions 108B can include a Ge atom concentration of about 45 atomic % to about 60 atomic % with any remaining atomic % being Si atoms. In some embodiments, for PFET 100, S/D sub-regions 108A and 108B can differ from each other based on p-type dopant (e.g., boron atoms) concentrations. For example, S/D sub-regions 108B can have a p-type dopant concentration higher than that in S/D sub-regions 108A. In some embodiments, S/D sub-regions 108A can be undoped. In some embodiments, S/D sub-regions 108B can include a boron dopant concentration of about 8×10²⁰ atoms/cm³ to about 3×10²¹ atoms/cm³.

In some embodiments, isolation structures 110 can be disposed under S/D regions 108 and in recessed regions of fin base 106. The recessed region in fin base 106 can be formed during the formation of S/D regions 108, as described in detail below. Isolation structures 110 can prevent the epitaxial growth of S/D regions 108 on fin base 106 and prevent the diffusion of dopants from S/D region 108 to fin base 106, thus preventing current leakage between S/D regions 108 and short channel effects in FET 100. In some embodiments, each isolation structure 110 can include (i) an undoped semiconductor layer 110A, (ii) a dielectric layer 110B, and (iii) an air spacer 110C, as shown in FIG. 1B. In some embodiments, isolation structure 110 can be without air spacers 110C, as shown in FIG. 1C.

In some embodiments, undoped semiconductor layer 110A can be disposed in the recessed region of fin base 106. In some embodiments, undoped semiconductor layer 110A can include undoped silicon or other suitable undoped semiconductor material and can have a width along an X-axis greater than that of S/D region 108. In some embodiments, top surface of undoped semiconductor layer 110A can have a width along an X-axis greater than that of S/D region 108. The vertical sidewalls of undoped semiconductor layer 110A can be misaligned with the vertical sidewalls of S/D region 108. The wider undoped semiconductor layer 110A can prevent the diffusion of dopants from S/D regions 108 to fin base 106. In some embodiments, top surface of undoped semiconductor layer 110A can be substantially coplanar with top surfaces of fin base 106. In some embodiments, undoped semiconductor layer 110A can extend a distance D1 of about 20 nm to about 40 nm into fin base 106. This distance D1 is equal to the recessed region formed in fin base 106 during the formation of S/D regions 108, as described in detail below. In some embodiments, if distance D1 is below about 20 nm, undoped semiconductor layer 110A may not adequately prevent the diffusion of dopants from S/D regions 108 to fin base 106. On the other hand, if distance D1 is above about 40 nm, the processing time (e.g., etching time, deposition time) for forming undoped semiconductor layer 110A increases, and consequently increases the manufacturing cost of FET 100.

In some embodiments, dielectric layer 110B can be disposed directly on undoped semiconductor layer 110A and can extend between a pair of inner gate spacers 126 that are disposed directly on fin base 106 and undoped semiconductor layer 110A. The sidewalls of these inner gate spacers 126 can be in direct contact with the sidewalls of dielectric layer 110B. In some embodiments, each dielectric layer 110B can include a nitride material, such as silicon nitride (SiN), silicon oxynitride (SiON), silicon oxycarbide (SiOC), silicon carbon oxynitride (SiCON), and silicon carbon nitride (SiCN). In some embodiments, each dielectric layer 110B can include a silicon-rich dielectric material. In some embodiments, the silicon-rich dielectric material can include (i) silicon-rich nitride (SiₓN_{y}) with a concentration of silicon atoms higher than the concentrations of nitrogen atoms, (ii) silicon-rich oxynitride (SiₓO_{y}N_{z}) with a concentration of silicon atoms higher than the concentrations of oxygen atoms and nitrogen atoms, (iii) silicon-rich oxycarbide (SiₓO_{y}C_{z}) with a concentration of silicon atoms higher than the concentrations of oxygen atoms and carbon atoms, (iv) silicon-rich oxycarbon nitride (Si_{w}OₓC_{y}N_{z}) with a concentration of silicon atoms higher than the concentrations of oxygen atoms, carbon atoms, and nitrogen atoms, (v) silicon-rich boron oxynitride (Si_{w}BₓO_{y}N_{z}) with a concentration of silicon atoms higher than the concentrations of oxygen atoms, boron atoms, and nitrogen atoms, (vi) silicon-rich boron oxycarbide (Si_{w}BₓO_{y}C_{z}) with a concentration of silicon atoms higher than the concentrations of oxygen atoms, boron atoms, and carbon atoms, or (vii) other suitable silicon-rich nitride- or carbide-based dielectric materials. The silicon-rich dielectric material of dielectric layer 110B can provide a high etch resistance to dielectric layer 110B during the formation of dielectric layer 110B, as discussed in detail below.

In some embodiments, air spacers 110C are disposed between dielectric layers 110B and S/D regions 108. Air spacers 110C can be formed as a result of the material of dielectric layers 110B inhibiting the epitaxial growth of S/D regions 108 on dielectric layers 110B. In addition, the structures of inner gate spacers 126 can control the growth of S/D sub-regions 108A along a Z-axis, which can prevent the bottommost S/D sub-regions 108A from contacting dielectric layers 108A, and consequently forming air spacers 110C. In some embodiments, air spacers 110C can have a thickness along a Z-axis of about 0.2 times to about 0.7 times thickness T2 of nanostructured channel regions 116. In some embodiments, dielectric layers 110B can have a thickness along a Z-axis of about 5 nm to about 15 nm. Within these ranges of thicknesses of dielectric layers 110B and air spacers 110C, dielectric layers 110B and air spacers 110C can prevent current leakage between S/D regions 108 and fin base 106 without compromising the size and manufacturing cost of FET 100. In some embodiments, air spacers 110C can be absent and dielectric layers 110B can be in contact with the backsides of S/D regions 10B, as shown in FIG. 1C. When air spacers 110C are not present in isolation structures 110, the thickness of dielectric layers 110B along a Z-axis can be substantially equal to the thickness of inner gate spacers 126 that are disposed directly on fin base 106 and undoped semiconductor layer 110A, as shown in FIG. 1C. Such thickness of dielectric layers 110B can adequately electrically isolate S/D regions 108 from fin base 106 without compromising the dimensions of FET 100.

In some embodiments, STI regions 130, ILD layers 132, and ESLs 134 can include dielectric materials, such as silicon oxide (SiO₂), SiN, SiON, SiCO, SiCN, SiCON, and other suitable dielectric materials. In some embodiments, ILD layers 132 can include an oxide material and ESLs 134 can include a nitride material different from ILD layers 132.

In some embodiments, nanostructured channel regions 116 can include semiconductor materials, such as Si, silicon arsenide (SiAs), silicon phosphide (SiP), SiC, SiCP, SiGe, Silicon Germanium Boron (SiGeB), Germanium Boron (GeB), Silicon-Germanium-Tin-Boron (SiGeSnB), a III-V semiconductor compound, or other suitable semiconductor materials. Though rectangular cross-sections of nanostructured channel regions 116 are shown, nanostructured channel regions 116 can have cross-sections of other geometric shapes (e.g., circular, elliptical, triangular, or polygonal). In some embodiments, nanostructured channel regions 116 can be in the form of nanosheets, nanowires, nanorods, nanotubes, or other suitable nanostructured shapes. As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm.

In some embodiments, gate structures 118 can be multi-layered structures and can surround each nanostructured channel region 116 for which gate structures 118 can be referred to as “GAA structures.” The different layers of gate structures 118 are not shown for simplicity. In some embodiments, each gate structure 118 can include (i) an interfacial oxide (IL) layer disposed on nanostructured channel regions 116, (ii) a high-k gate dielectric layer disposed on the IL layer, and (iii) a conductive layer disposed on the high-k gate dielectric layer. In some embodiments, the IL layer can include SiO₂, silicon germanium oxide (SiGeOₓ), or germanium oxide (GeOₓ). In some embodiments, the high-k gate dielectric layer can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), zirconium aluminum oxide (ZrAlO), zirconium silicate (ZrSiO₂), lanthanum oxide (La₂O₃), aluminum oxide (Al₂O₃) zinc oxide (ZnO), hafnium zinc oxide (HfZnO), and yttrium oxide (Y₂O₃).

In some embodiments, the conductive layer can be a multi-layered structure. The different layers of the conductive layer are not shown for simplicity. Each conductive layer can include a work function metal (WFM) layer disposed on the high-k gate dielectric layer and a gate metal fill layer disposed on the WFM layer. In some embodiments, the WFM layer can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for NFET 100. In some embodiments, the WFM layer can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu) for PFET 100. The gate metal fill layers can include a suitable conductive material, such as tungsten (W), Ti, silver (Ag), ruthenium (Ru), molybdenum (Mo), copper (Cu), cobalt (Co), Al, iridium (Ir), nickel (Ni), metal alloys, and a combination thereof.

Conductive capping layers 120 can be disposed directly on gate structures 118. Conductive capping layers 120 can provide conductive interfaces between gate structures 118 and gate contact structures 128 to electrically connect gate structures 118 to gate contact structures 128 without forming gate contact structures 128 directly on or within gate structures 118. Gate contact structures 128 are not formed directly on or within gate structures 118 to prevent contamination by any of the processing materials used in the formation of gate contact structures 128. Contamination of gate structures 118 can lead to the degradation of device performance. Thus, with the use of conductive capping layers 120, gate structures 118 can be electrically connected to gate contact structures 128 without compromising the integrity of gate structures 118. In some embodiments, conductive capping layer 120 can have a thickness of about 1 nm to about 8 nm for adequately providing a conductive interface between gate structures 118 and gate contact structures 128 without compromising the size and manufacturing cost of FET 100. In some embodiments, conductive capping layers 120 can include a metallic material, such as W, Ru, Mo, Co, other suitable metallic materials, and a combination thereof.

Insulating capping layers 122 can be disposed directly on conductive capping layers 120. Insulating capping layers 122 can protect the underlying conductive capping layers 120 from structural and/or compositional degradation during subsequent processing of FET 100. In some embodiments, insulating capping layers 122 can include a dielectric nitride or carbide material, such as SiN, SION, SiCN, SiC, SiCON, and other suitable dielectric nitride or carbide materials. In some embodiments, insulating capping layers 122 can have a thickness of about 5 nm to about 10 nm for adequate protection of the underlying conductive capping layers 120 without compromising the size and manufacturing cost of FET 100. In some embodiments, top surfaces of insulating capping layers 122 can be substantially coplanar with top surfaces of ILD layers 132.

In some embodiments, gate structures 118 can be electrically isolated from adjacent S/D contact structures 114 by outer gate spacers 124 and the portions of gate structures 118 surrounding nanostructured channel regions 116 can be electrically isolated from adjacent S/D regions 108 by inner gate spacers 126. Outer gate spacers 124 and inner gate spacers 126 can include a material similar to or different from each other. In some embodiments, outer gate spacers 124 and inner gate spacers 126 can include an insulating material, such as SiO₂, SiN, SiON, SiCO, SiCN, SiCON, and other suitable insulating materials. In some embodiments, inner gate spacers 126 can have a dielectric material similar to that of dielectric layer 110B.

In some embodiments, each inner gate spacer 126 can have a thickness of about 1 nm to about 10 nm along a Z-axis. Within this range of thickness, adequate electrical isolation can be provided by inner gate spacers 126 between gate structures 108 and adjacent S/D regions 108 without compromising the size and manufacturing cost of FET 100. In some embodiments, inner gate spacers 126 can have spacer portions 126a that extend towards S/D sub-regions 108B and past the sidewalls of nanostructured channel regions 116 facing S/D sub-regions 108B. These extended spacer portions 126a can control the epitaxial growth of S/D sub-regions 108A along a Z-axis to limit thicknesses T1 of S/D sub-regions 108A to be equal to or less than thicknesses T2 of nanostructured channel regions 116 and to limit vertex angles A to be less than 90 degrees. With such controlled epitaxial growth of S/D sub-regions 108A, adjacent S/D sub-regions 108A can be prevented from merging with each other and the bottommost S/D sub-regions 108A can be prevented from blocking the air gaps in air spacers 110C. Thus, except for bottommost inner gate spaces 126, each inner gate spacer 126 has (i) a first portion directly in contact with top and bottom surfaces of adjacent nanostructured channel regions 116, and (ii) a second portion directly in contact with top and bottom surfaces of adjacent S/D sub-region 108A. Each of bottommost inner gate spaces 126 has (i) a first portion directly in contact with a top surface of underlying fin base 106 and a bottom surface of overlying bottommost nanostructured channel region 116, and (ii) a second portion directly in contact with a top surface of underlying undoped semiconductor layer 110A and a bottom surface of overlying bottommost S/D sub-region 108A.

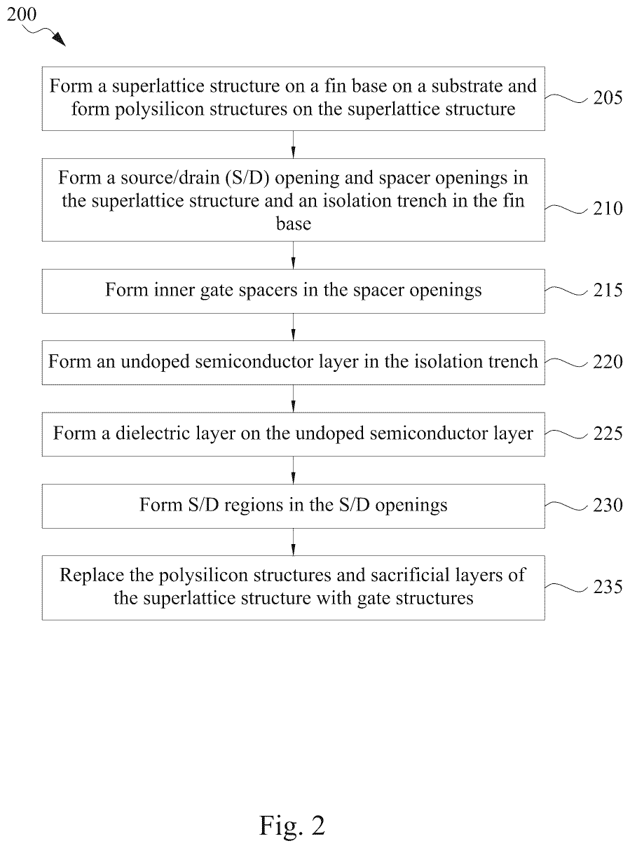

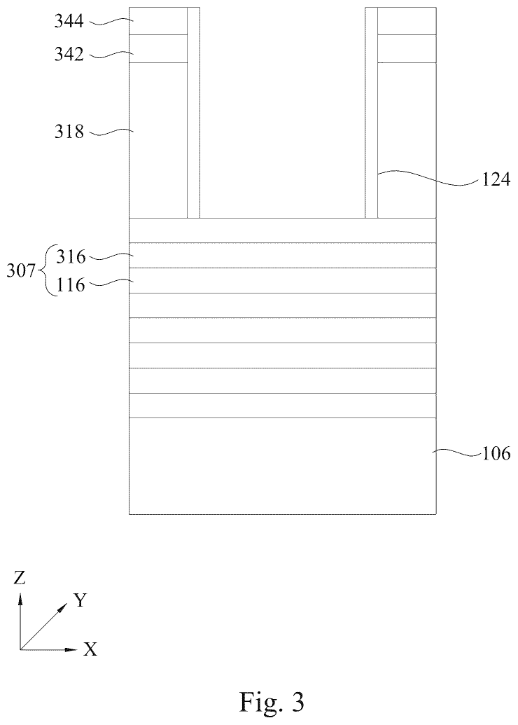

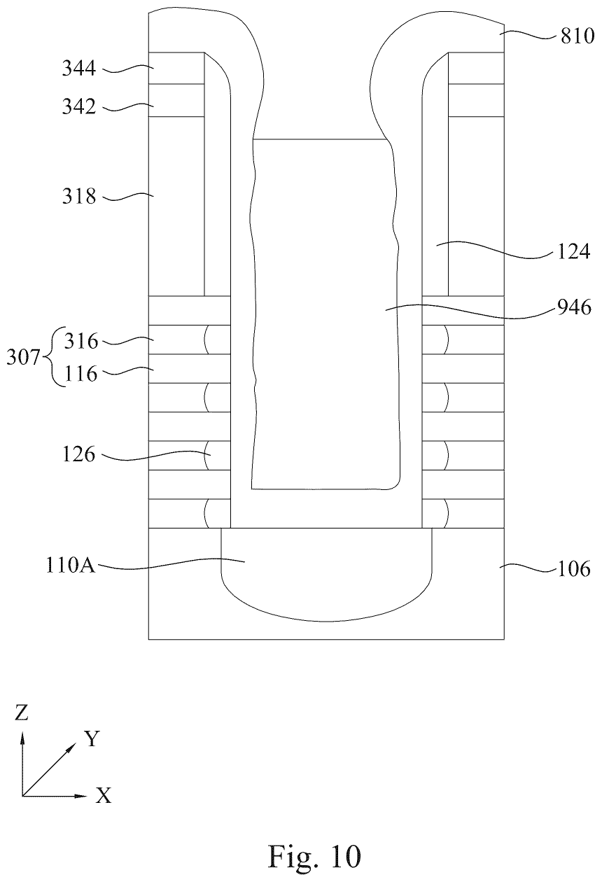

FIG. 2 is a flow diagram of an example method 200 for fabricating FET 100 with cross-sectional view shown in FIG. 1B, according to some embodiments. For illustrative purposes, the operations illustrated in FIG. 2 will be described with reference to the example fabrication process for fabricating FET 100 as illustrated in FIGS. 3-16. FIGS. 3-16 are cross-sectional views of FET 100 along line A-A of FIG. 1A at various stages of its fabrication, according to some embodiments. Operations can be performed in a different order or not performed depending on specific applications. It should be noted that method 200 may not produce a complete FET 100. Accordingly, it is understood that additional processes can be provided before, during, and after method 200, and that some other processes may only be briefly described herein. Elements in FIGS. 3-16 with the same annotations as elements in FIGS. 1A-1B are described above.

In operation 205, a superlattice structure is formed on a fin base on a substrate, and polysilicon structures are formed on the superlattice structure. For example, as described with reference to FIG. 3, fin base 106 is formed on substrate 104, superlattice structure 307 is formed on fin base 106, and polysilicon structures 318 are formed on superlattice structure 307. In some embodiments, hard mask layers 342 and 344 can be formed during the formation of polysilicon structures 318. Superlattice structure 307 can include nanostructured layers 116 and 316 arranged in an alternating configuration. In some embodiments, nanostructured layers 116 and 316 include materials different from each other. In some embodiments, nanostructured layers 116 can include Si and nanostructured layers 316 can include SiGe. Nanostructured layers 316 are also referred to as “sacrificial layers 316.” During subsequent processing, polysilicon structures 318, hard mask layers 342 and 344, and sacrificial layers 316 can be replaced with gate structures 118 in a gate replacement process. In some embodiments, outer gate spacers 124 can be formed after the formation of polysilicon structures 318.

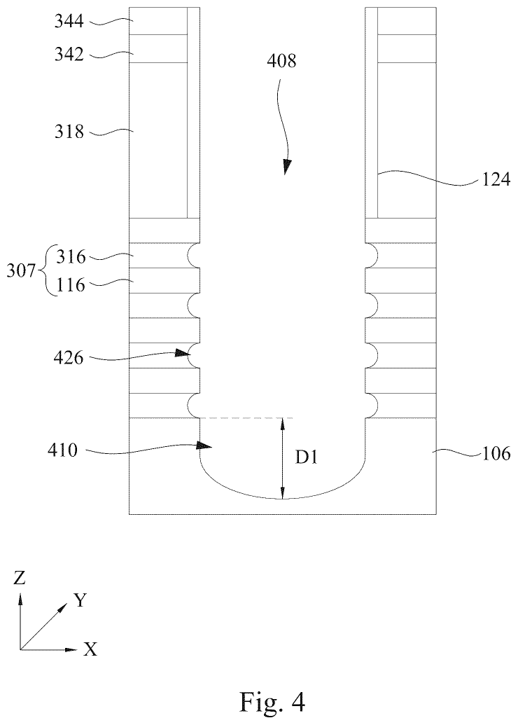

Referring to FIG. 2, in operation 210, a S/D opening and spacer openings are formed in the superlattice structure and an isolation trench is formed in the fin base. For example, as described with reference to FIG. 4, a S/D opening 408 and spacer openings 426 are formed in superlattice structure 307 and an isolation trench 410 is formed in fin base 106. S/D opening 408 can be formed by etching the portions of superlattice structure 307 not covered by polysilicon structures 318. The formation of S/D opening 408 can be followed by the formation of isolation trench 410 extending distance D1 into fin base 106. In some embodiments, isolation trench 410 can be formed by performing an etching process on a portion of fin base 106 exposed in S/D opening 408.

In some embodiments, the etching of superlattice structure 307 and fin base 106 can include a plasma-based dry etching process using etching gases, such as carbon tetrafluoride (CF₄), sulfur dioxide (SO₂), hexafluoroethane (C₂F₆), chlorine (Cl₂), nitrogen trifluoride (NF₃), sulfur hexafluoride (SF₆), and hydrogen bromide (HBr), with mixture gases, such as hydrogen (H₂), oxygen (O₂), nitrogen (N₂), and argon (Ar). The etching can be performed at a temperature ranging from about 25° C. to about 200° C. under a pressure from about 5 mTorr to about 50 mTorr. The flow rate of the etching gases can range from about 5 standard cubic centimeters per minute (sccm) to about 100 sccm. The plasma power can range from about 50 W to about 200 W with a bias voltage from about 30 V to about 200 V.

The formation of isolation trench 410 can be followed by the formation of spacer openings 426 by performing an etching process on sidewalls of sacrificial layers 316 facing S/D openings 408. The etching process can laterally etch sacrificial layers 316 to laterally recess the sidewalls of sacrificial layers 316 with respect to sidewalls of nanostructured layers 116 facing S/D openings 408. The etching process can include a dry etching process that has a higher etch selectivity for SiGe of sacrificial layers 316 than Si of nanostructured layers 116. For example, halogen-based chemistries can exhibit etch selectivity that is higher for Ge than for Si. Therefore, halogen gases can etch SiGe faster than Si. In some embodiments, the halogen-based chemistries can include fluorine-based and/or chlorine-based gasses. Alternatively, the etching of sacrificial layers 316 can include a wet etching process with a higher selectivity for SiGe than Si. For example, the wet etching process can include using a mixture of sulfuric acid (H₂SO₄) and hydrogen peroxide (H₂O₂) and/or a mixture of ammonia hydroxide (NH₄OH) with H₂O₂ and deionized (DI) water.

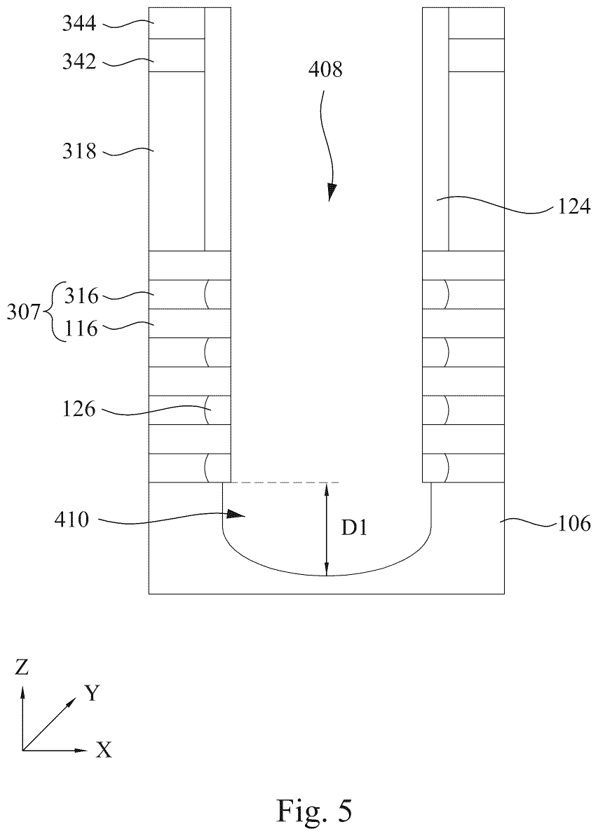

Referring to FIG. 2, in operation 215, inner gate spacers are formed in the spacer openings. For example, as described with reference to FIG. 5, inner gate spacers 126 are formed in spacer openings 426. The formation of inner gate spacers 126 can include sequential operations of (i) depositing a dielectric material layer (not shown) on the structure of FIG. 4, and (ii) etching the dielectric material layer to form the structure of FIG. 5. In some embodiments, the etching of the dielectric material layer can be an anisotropic dry etching process and can have a higher etching rate along a Z-axis rather than along an X-axis or a Y-axis. As a result, the portions of the dielectric material layer in S/D openings 408 and isolation trench 410 can be etched without etching the portions of the dielectric material layer in spacer openings 426.

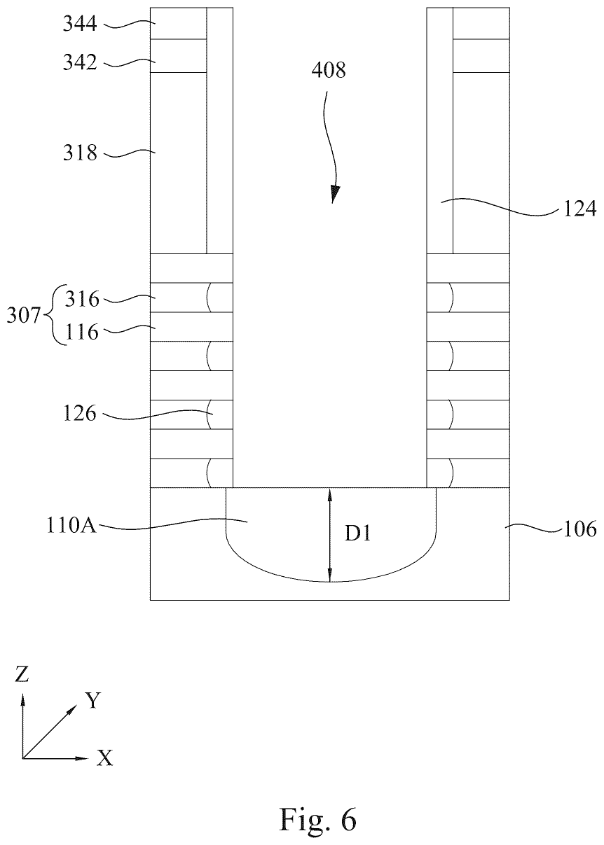

Referring to FIG. 2, in operation 220, an undoped semiconductor layer is formed in the isolation trench. For example, as described with reference to FIG. 6, undoped semiconductor layer 110A is formed in isolation trench 410. In some embodiments, the formation of undoped semiconductor layer 110A can include epitaxially growing an undoped silicon layer on the exposed surfaces of fin base 106 in isolation trench 410.

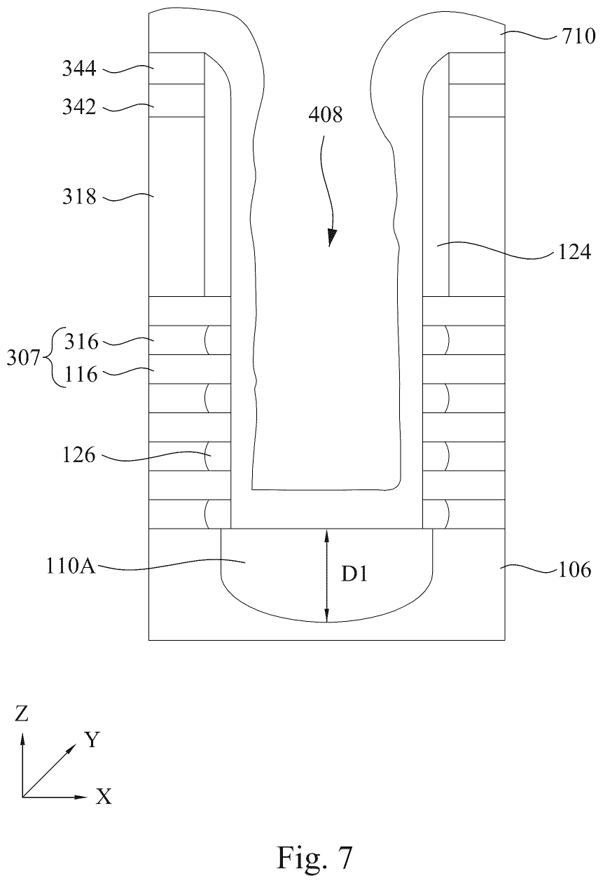

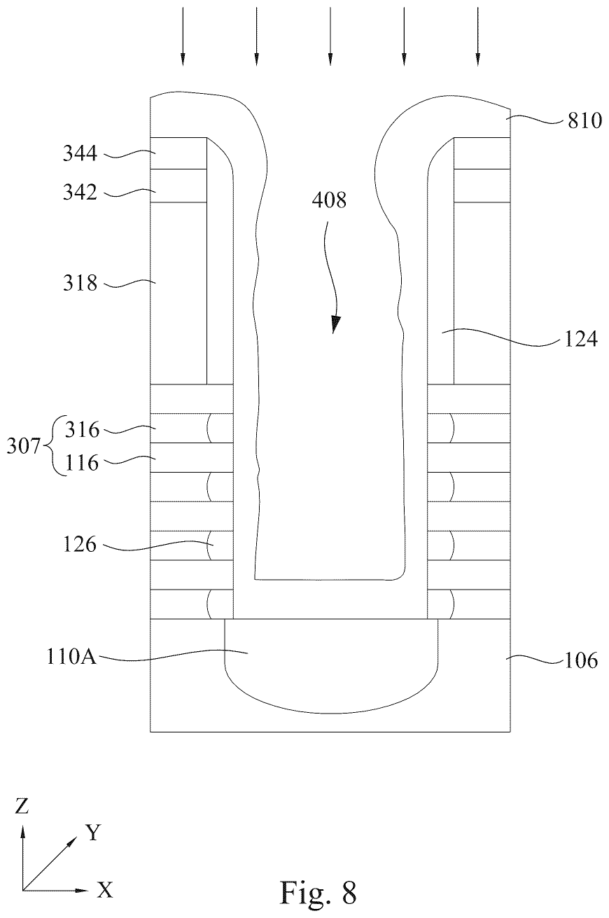

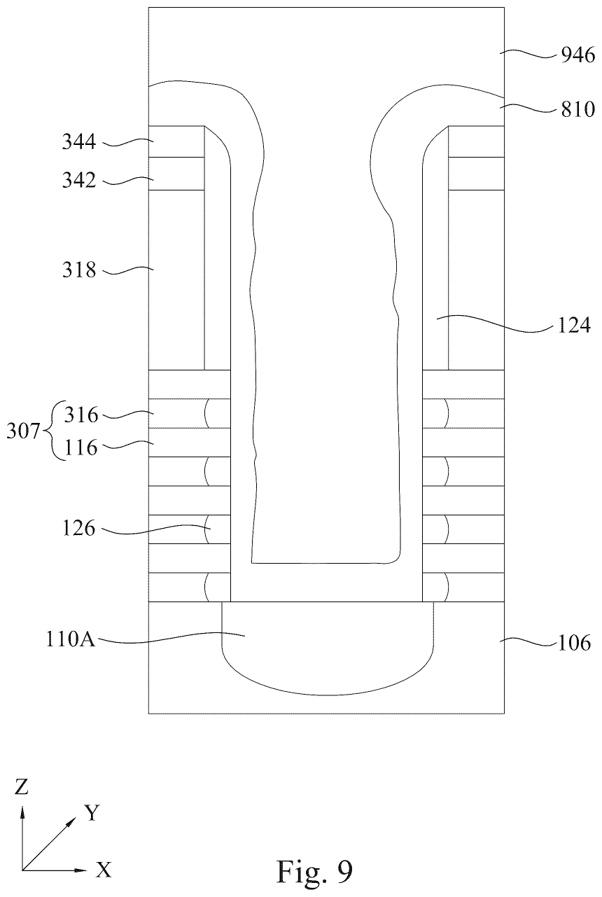

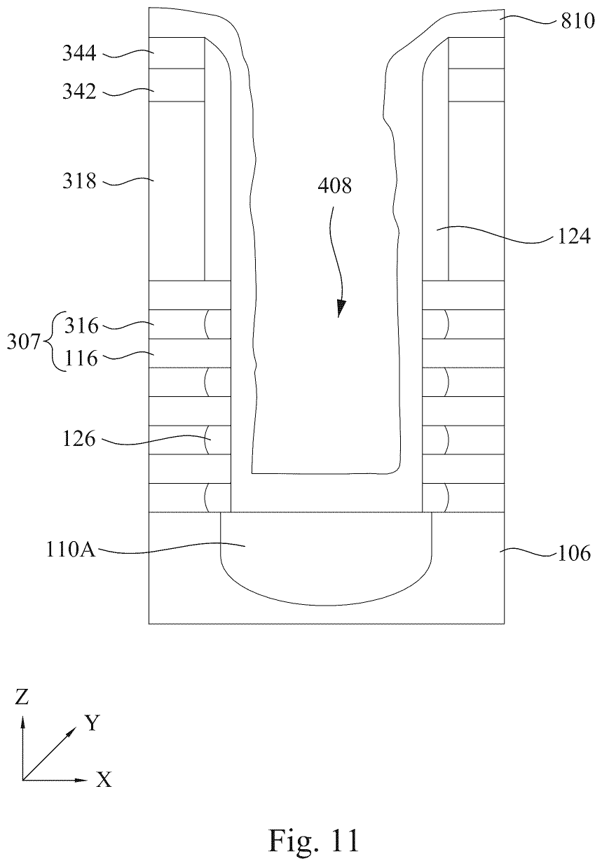

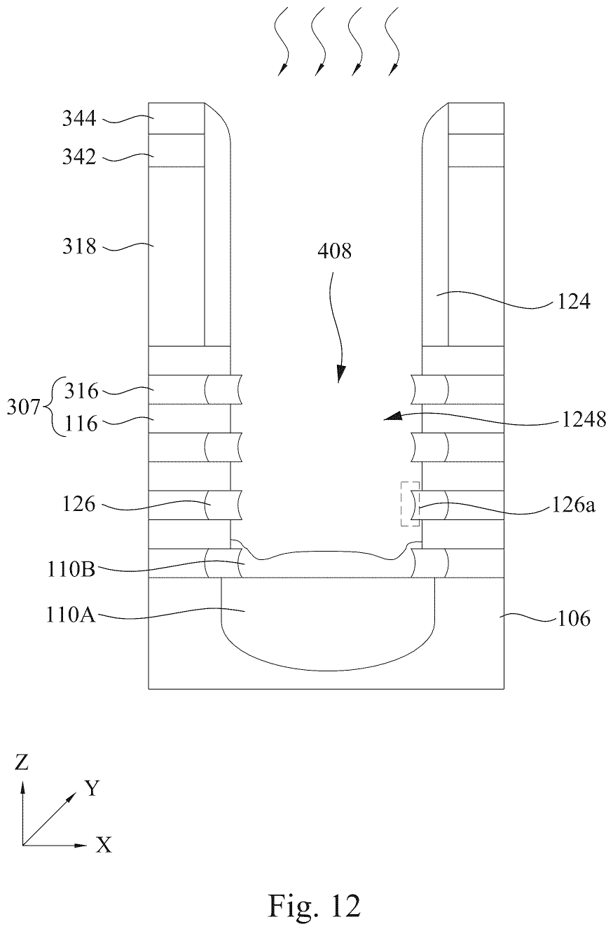

Referring to FIG. 2, in operation 225, a dielectric layer is formed on the undoped semiconductor layer. For example, as described with reference to FIGS. 7-12, dielectric layer 110B is formed on undoped semiconductor layer 110A. In some embodiments, dielectric layer 110B can include silicon-rich dielectric material. The formation of dielectric layer 110B with silicon-rich dielectric material can include sequential steps of (i) depositing a dielectric layer 710 on the structure of FIG. 6 to form the structure of FIG. 7, (ii) performing an ion implantation process on dielectric layer 710 to form a dielectric layer 810 with silicon-rich dielectric material, as shown in FIG. 8, (iii) depositing a bottom anti-reflective coating (BARC) layer 946 on dielectric layer 810, as shown in FIG. 9, (iv) etching BARC layer 946 to expose top portions of dielectric layer 810 that are thicker than sidewall and bottom portions of dielectric layer 810, (v) performing an etch process on the exposed top portions of dielectric layer 810 to thin down the top portions, as shown in FIG. 11, (vi) removing BARC layer 946 to expose dielectric layer 810, as shown in FIG. 11, (vii) performing an etch process on dielectric layer 810 to remove top and sidewall portions of dielectric layer 810 and form dielectric layer 110B, as shown in FIG. 12, and (viii) performing an anneal process on the structure of FIG. 12 to densify dielectric layer 110B.

In some embodiments, depositing dielectric layer 710 can include depositing a layer of SiN, SiON, SiOC, SiCON, or other suitable silicon nitride- or carbide-based dielectric material with a stoichiometric composition. In some embodiments, performing the ion implantation process on dielectric layer 710 can convert the silicon nitride- or carbide-based dielectric material of dielectric layer 710 into a silicon-rich nitride- or carbide-based dielectric material, such as SiₓN_{y}, SiₓO_{y}N_{z}, SiₓO_{y}C_{z}, and Si_{w}OₓC_{y}N_{z}. Converting the stoichiometric composition of dielectric layer 710 into the non-stoichiometric composition of dielectric layer 810 with silicon-rich dielectric material can harden dielectric layer 810 and increase the etch resistance of dielectric layer 810 compared to that of dielectric layer 710. Due to the directionality of ion implantation along a Z-axis, the bottom portion of dielectric layer 810 that is disposed on undoped semiconductor layer 110A can have a higher concentration of silicon atoms than that in sidewalls of dielectric layer 810. As a result, the bottom portion of dielectric layer 810 can have a higher etch resistance than that of the sidewalls of dielectric layer 810. The higher etch resistance of the bottom portion of dielectric layer 810 can prevent or minimize the loss of the bottom portion of dielectric layer 810 during the etching of the top and sidewalls portions of dielectric layer 810 to form dielectric layer 110B, as shown in FIG. 12. The higher etch resistance can also prevent or minimize the loss of dielectric layer 110B during subsequent etching processes performed during the formation of S/D regions 108.

In some embodiments, the ion implantation process can include implanting silicon atoms with a dosage of about 1×10¹⁴ ions/cm³ to about 1×10¹⁷ ions/cm³ and an energy of about 1 KeV to about 3 KeV. If the ion implantation energy is lower than 1 KeV and/or the ion implantation dosage is less than 1×10¹⁴ ions/cm³, dielectric layer 810 is not formed with adequate etch resistance to prevent or minimize the loss of the bottom portion of dielectric layer 810 during the etching of the top and sidewalls portions of dielectric layer 810. On the other hand, if the ion implantation energy is higher than 3 KeV and/or the ion implantation dosage is greater than 1×10¹⁷ ions/cm³, dielectric layer 810 is formed with an ultra-high etch resistance, which increases the etching time for removing the top and sidewalls portions of dielectric layer 810, and consequently increases the device manufacturing cost. In some embodiments, the etch process to remove the top and sidewall portions of dielectric layer 810 can include a wet etching process using dilute hydrofluoric acid (DHF). In some embodiments, during the etching of dielectric layer 810, sidewall portions of nanostructured channel regions 116 can be etched and form recessed regions 1248 between extended spacer portions 126a.

In some embodiments, the anneal process can be performed at a temperature of about 500° C. to about 600° C. to densify dielectric layer 110B and further increase the etch resistance of dielectric layer 110B to prevent or minimize the loss of dielectric layer 110B during subsequent etching processes performed during the formation of S/D regions 108. In some embodiments, the anneal process on dielectric layer 110B is not performed if the ion implantation process is performed. In some embodiments, if dielectric layer 110B is formed with stoichiometric composition of dielectric material, the ion implantation process is not performed and the anneal process on dielectric layer 110B is performed to densify dielectric layer 110B.

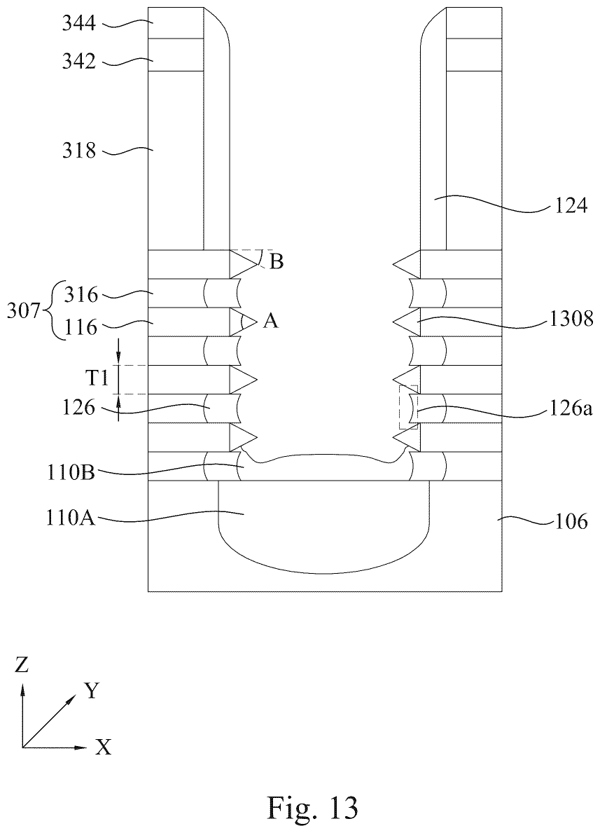

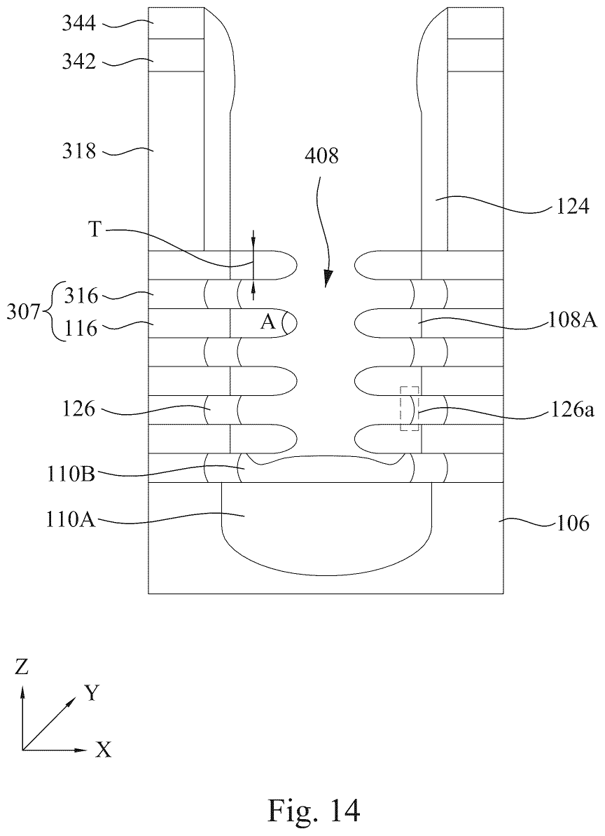

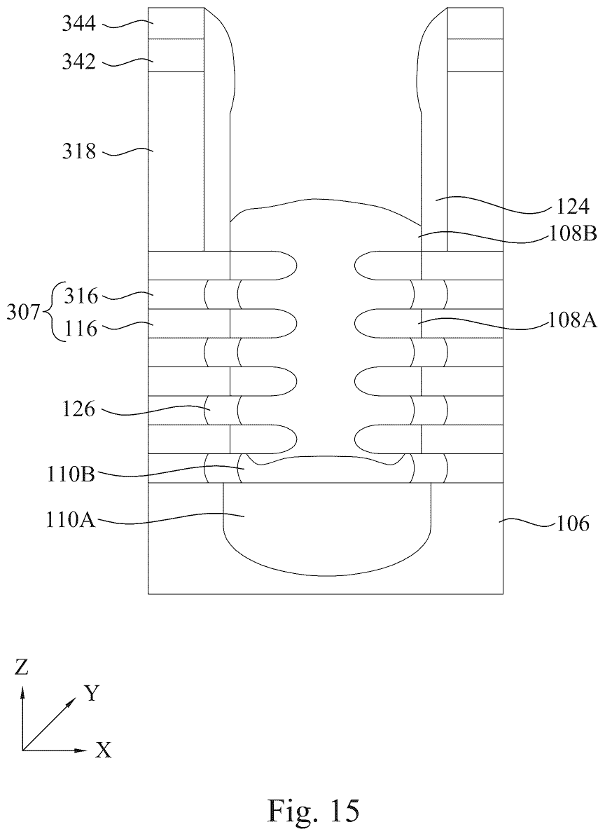

Referring to FIG. 2, in operation 230, S/D regions are formed in the S/D openings. For example, as described with reference to FIGS. 13-15, S/D regions 108 are formed in S/D openings 408. The formation of S/D regions 108 can include sequential operations of (i) epitaxially growing S/D sub-regions 108A on sidewalls of nanostructured layers 116 in recessed region 1248, as shown in FIGS. 13 and 14, and (ii) epitaxially growing S/D sub-regions 108B on S/D sub-regions 108A, as shown in FIG. 15. In some embodiments, the epitaxial growth of S/D sub-regions 108A can start with the formation of triangular-shaped epitaxial structures 1308 in recessed regions 1248, as shown in FIG. 13, and proceed to form epitaxial structures of S/D sub-regions 108A, as shown in FIG. 14. Due to the growth of epitaxial structures 1308 in recessed regions 1248, the dimensions of epitaxial structures 1308 can be limited by the extended spacer portions 126a of inner gate spacers 126. And, since the epitaxial structures of S/D sub-regions 108A build on epitaxial structures 1308, the dimensions of S/D sub-regions 108A can be limited by the dimensions of epitaxial structures 1308. Thus, by growing epitaxial structures 1308 in recessed regions 124, epitaxial structures 1308 and S/D sub-regions 108A can be formed with smaller thicknesses T1 and vertex angles A compared to epitaxial structures grown without being restricted by inner gate spacers.

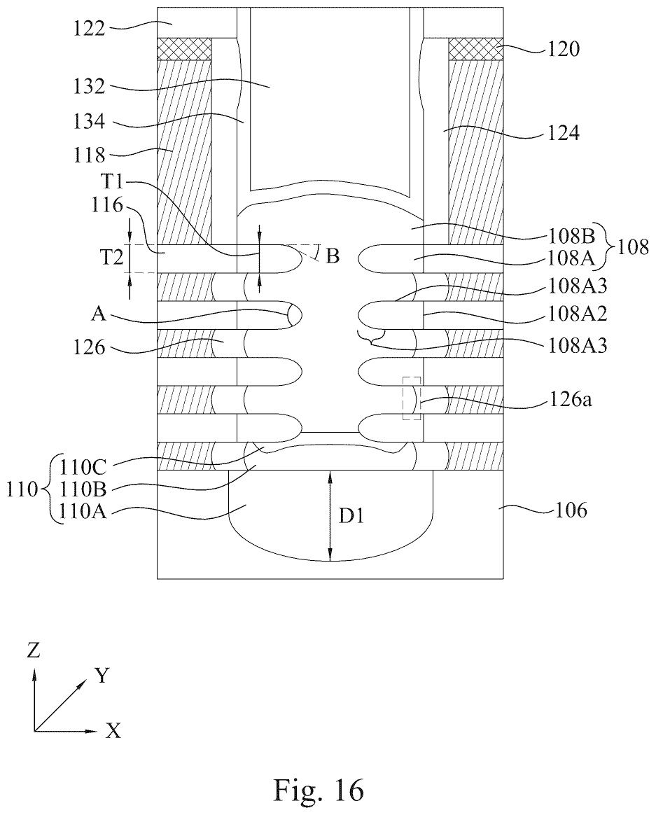

In some embodiments, the formation of S/D regions 108 can be followed by the formation of ILD layers 132 and ESLs 134, as shown in FIG. 16.

Referring to FIG. 2, in operation 235, the polysilicon structures and sacrificial layers of the superlattice structure are replaced with gate structures. For example, as described with reference to FIG. 16, polysilicon structures 318 and sacrificial layers 316 are replaced with gate structures 118. The formation of gate structures 118 can include removing hard mask layers 342 and 344, polysilicon structures 318, and sacrificial layers 316 from the structure of FIG. 15 to form gate openings (not shown), and forming gate structures 118 in the gate openings, as shown in FIG. 16. In some embodiments, the formation of gate structures 118 can be followed by the formation of conductive capping layers 120 and insulating capping layers 122, as shown in FIG. 16.

In some embodiments, method 200 of FIG. 2 can be used to form NFET 100 and PFET 100 substantially parallel to each other on substrate 104. In some embodiments, the elements of NFET 100 and PFET 100 can be formed at the same time, except for their S/D regions, which can be formed sequentially.

The present disclosure provides examples methods (e.g., method 200) of forming isolation structures (e.g., isolation structures 110) between the epitaxial S/D regions (e.g., S/D regions 108) and fin bases (e.g., fin base 106). These isolation structures can electrically isolate the epitaxial S/D regions from the underlying fin bases, and as a result prevent or minimize current leakage between adjacent S/D regions on the same fin base. In some embodiments, each of the isolation structures can include an undoped semiconductor layer (e.g., undoped semiconductor layer 110A), a dielectric layer (e.g., dielectric layer 110B) disposed on the semiconductor layer, and an air spacer (e.g., air spacer 110C) disposed on the dielectric layer. In some embodiments, the undoped semiconductor layer can include an undoped silicon layer epitaxially grown in a portion of the fin base under the epitaxial S/D region. In some embodiments, the dielectric layer can include a silicon-rich dielectric material. As used herein, the term “silicon-rich dielectric material” refers to a dielectric material with a non-stoichiometric composition, which has a concentration ratio of silicon to any other chemical element of the dielectric material higher than that of the dielectric material with a stoichiometric composition. In some embodiments, the silicon-rich dielectric material can include (i) silicon-rich nitride (SiₓN_{y}) with a concentration of silicon atoms higher than the concentrations of nitrogen atoms, (ii) silicon-rich oxynitride (SiₓO_{y}N_{z}) with a concentration of silicon atoms higher than the concentrations of oxygen atoms and nitrogen atoms, (iii) silicon-rich oxycarbide (SiₓO_{y}C_{z}) with a concentration of silicon atoms higher than the concentrations of oxygen atoms and carbon atoms, or (iv) other suitable silicon-rich nitride- or carbide-based dielectric materials.

In some embodiments, a semiconductor device includes a substrate, a fin base disposed on the substrate, nanostructured channel regions disposed on a first portion of the fin base, a gate structure surrounding the nanostructured channel regions, a source/drain (S/D) region disposed on a second portion of the fin base, and an isolation structure disposed between the S/D region and the second portion of the fin base. The isolation structure includes an undoped semiconductor layer disposed on the second portion of the fin base, a silicon-rich dielectric layer disposed on the undoped semiconductor layer, and an air spacer disposed on the silicon-rich dielectric layer.

In some embodiments, a semiconductor device includes a substrate, a fin base disposed on the substrate, nanostructured channel regions disposed on the fin base, a source/drain (S/D) region disposed on the fin base, an undoped semiconductor layer disposed between the fin base and the S/D region, and a silicon-rich dielectric layer disposed between the undoped semiconductor layer and the S/D region.

In some embodiments, a method includes forming a stack of first and second nanostructured layers in an alternating configuration on a fin base, forming a polysilicon structure on a first portion of the stack of first and second nanostructured layers, forming a first opening in a second portion of the stack of first and second nanostructured layers uncovered by the polysilicon structure, forming a second opening in a portion of the fin base under the first opening, forming third openings in the first portion of the stack of first and second nanostructured layers, depositing a dielectric layer to fill the third openings, growing an epitaxial layer in the first opening, forming a silicon-rich dielectric layer in the first opening and on the epitaxial layer, and forming a S/D region on sidewalls of the first nanostructured layers in the first opening.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a fin base disposed on the substrate;
nanostructured channel regions disposed on the fin base;
a gate structure surrounding the nanostructured channel regions;
a source/drain (S/D) region disposed on the fin base; and
an isolation structure, disposed between the S/D region and the fin base, comprising:
a semiconductor layer disposed in the fin base; and
an air spacer disposed between the semiconductor layer and a bottom surface of the S/D region.

2. The semiconductor device of claim 1, wherein the semiconductor layer extends below the nanostructured channel regions.

3. The semiconductor device of claim 1, wherein the semiconductor layer comprises an undoped silicon layer.

4. The semiconductor device of claim 1, wherein the semiconductor layer comprises a width greater than a width of the S/D region.

5. The semiconductor device of claim 1, further comprising inner gate spacers disposed directly on the fin base and the semiconductor layer.

6. The semiconductor device of claim 1, further comprising a dielectric layer between the semiconductor layer and the air spacer, wherein the dielectric layer comprises a silicon-rich nitride layer.

7. The semiconductor device of claim 6, further comprising inner gate spacers disposed directly on the fin base and in contact with sidewalls of the dielectric layer.

8. The semiconductor device of claim 1, wherein the S/D region comprises S/D sub-regions disposed on sidewalls of the nanostructured channel regions and non-overlapping with each other.

9. The semiconductor device of claim 8, wherein a ratio of a thickness of the nanostructured channel regions and a thickness of the S/D sub-regions is about 1:1 to about 1:4.

10. The semiconductor device of claim 1, wherein a thickness of the air spacer is about 0.2 times to about 0.7 times a thickness of the nanostructured channel regions.

11. A semiconductor device, comprising:
a substrate;
a fin base disposed on the substrate;
nanostructured channel regions disposed on the fin base;
a source/drain (S/D) region disposed on the fin base;
a silicon layer disposed between the fin base and the S/D region; and
a silicon-rich dielectric layer disposed between the silicon layer and the S/D region.

12. The semiconductor device of claim 11, further comprising spacers disposed directly on the fin base and on ends of the silicon-rich dielectric layer.

13. The semiconductor device of claim 11, further comprising spacers directly in contact with top surfaces of the fin base and the silicon layer.

14. The semiconductor device of claim 11, wherein the S/D region comprises sub-regions with tapered tip regions disposed on sidewalls of the nanostructured channel regions.

15. The semiconductor device of claim 11, wherein the silicon-rich dielectric layer comprises a silicon-rich nitride layer or a silicon-rich oxynitride layer.

16. The semiconductor device of claim 11, further comprising an air spacer disposed between the S/D region and the silicon-rich dielectric layer.

17. A method, comprising:
forming a stack of first and second nanostructured layers on a fin base;
forming a polysilicon structure on the stack of first and second nanostructured layers;
etching an opening through the stack of first and second nanostructured layers and into the fin base;
growing an epitaxial layer in the opening;
forming a silicon-rich dielectric layer in the opening and on the epitaxial layer; and
forming a S/D region on sidewalls of the first nanostructured layers in the opening.

18. The method of claim 17, wherein forming the silicon-rich dielectric layer comprises:
depositing a dielectric layer with a stoichiometric composition; and
performing a silicon ion implantation on the dielectric layer.

19. The method of claim 17, wherein forming the silicon-rich dielectric layer comprises performing an anneal process on the silicon-rich dielectric layer.

20. The method of claim 17, wherein growing the epitaxial layer comprises epitaxially growing an undoped silicon layer in the opening.
